(19) United States
(12) Patent Application Publication
(10) Pub. No.: US 2009/0309460 A1
(43) Pub. Date: Dec. 17, 2009

(54) INSULATION PIEZOELECTRIC TRANSFORMER

(76) Inventors: Tao-Chin Wei, Taipei City (TW); Ming Shing Chou, Taoyuan City (TW); Hsi Chen Chang, Tucheng City (TW)

Correspondence Address: SINORICA, LLC, 2275 Research Blvd., Suite 500, ROCKVILLE, MD, 20850, US

(21) Appl. No.: 12/179,621

(22) Filed: Jul. 25, 2008

(30) Foreign Application Priority Data
Jun. 13, 2008 (TW) 97122184

(51) Int. Cl. H01L 41/047

(52) U.S. Cl. 310/359

(57) ABSTRACT

The present invention discloses an insulation piezoelectric transformer, wherein upper electrodes and corresponding lower electrodes are respectively formed on the upper surface and lower surface of a ceramic substrate to form the primary side and the secondary side. A high DC voltage is applied to the primary side and the secondary side to polarize the ceramic material in between the upper and lower electrodes. The unpolarized portion of substrate still keeps the properties of a ceramic material and functions as an insulator of the primary and secondary sides. Therefore, the present invention functions as an insulation piezoelectric transformer.

### BACKGROUND OF THE INVENTION

1. Field of the Invention

The present invention relates to a piezoelectric transformer, particularly to an insulation piezoelectric transformer, wherein the unpolarized portion of the substrate, which still has the properties of ceramic, is used to insulate the secondary side from the primary side.

2. Description of the Related Art

Isolation transformers are generically referred to noise-proof transformers. Before entering an electronic device, a source power will be processed by a source power transformer. However, high-frequency noise can still reach the secondary side and enter the electronic device via the capacitive effect, magnetic coupling or electromagnetic radiation between the primary side and the secondary side. A source power has to meet the device. A small isolation transformer is enough for a small-power device. A high-power device may need a very giant transformer. This is the reason why the weight of an industrial isolation transformer sometimes reaches as high as over one hundred kilograms.

To meet the tendency of fabricating slim, lightweight and compact products, LCD (Liquid Crystal Display) backlight modules have extensively adopted piezoelectric transformers to drive the CCFL (Cold Cathode Fluorescent Lamp) thereof recently, especially in notebook computers. The piezoelectric transformer can perform a conversion between mechanical energy and electric energy. When a sinusoidal AC (Alternating Current) voltage having a frequency near the resonant frequency is fed into the input end (the activating side) of a piezoelectric device, the inverse piezoelectric effect will induce the piezoelectric element to resonate. Then, the direct piezoelectric effect will transform the mechanical energy of resonance into electric energy, and the electric energy is output from the output end (the energy conversion side). Thus is completed a power conversion. The piezoelectric transformer has the following advantages: high power density (over 40 W/cm³), high energy conversion efficiency (97%), high piezoelectric ratio, high reliability, low thickness, small size, lightweight, less generated heat, high insulation performance, incombustibility, low price, none winding, none magnetic core, single-piece structure, automatic production, and none electromagnetic interference.

The conventional piezoelectric transformer cannot meet the safety regulation of direct current unless a traditional transformer is used to isolate the secondary side from the primary side. However, the efficiency thereof is reduced. A Taiwan patent No. 492204 disclosed a high output laminated piezoelectric transformer, which achieves a high output with a low-speed oscillation, whereby less heat is generated. The prior-art piezoelectric transformer adopts a multi-layer composite material, wherein the insulation layer and other layers are made of different materials. Therefore, the prior-art piezoelectric transformer has a high power loss. When a high voltage is input, the laminated material will vibrate so violently that the laminated material is likely to break or fracture. As energy conducted in different materials cannot be coupled, the prior-art piezoelectric transformer cannot meet the safety regulation demand that the secondary side should be isolated from the primary side. Therefore, the prior-art piezoelectric transformer cannot function as an insulation piezoelectric transformer.

### SUMMARY OF THE INVENTION

The primary objective of the present invention is to provide an insulation piezoelectric transformer, which can isolate the secondary side form the primary side and thus can solve the conventional problems.

To achieve the abovementioned objective, the present invention proposes an insulation piezoelectric transformer, which comprises a substrate, a first upper electrode, a first lower electrode, a second upper electrode and a second lower electrode. The substrate is made of a ceramic material and has an upper surface and a lower surface. The first and second upper electrodes are formed on the upper surface of the substrate but do not contact each other. The first and second lower electrodes are formed on the lower surface of the substrate but do not contact each other. The first upper and lower electrodes are symmetrical to each other and form the primary side. The second upper and lower electrodes are symmetrical to each other and form the secondary side. A high DC (Direct Current) voltage is applied to the primary and secondary sides to polarize the substrate in between the upper and lower electrodes, but the unpolarized central portion of the substrate still keeps the properties of a ceramic material. When the input is a voltage without frequency, the unpolarized central portion of the substrate can function as an insulator of the primary and secondary sides. Contrary to the conventional piezoelectric transformers that use a composite material, the present invention adopts a single-layer design and is exempt from the risk of fracture under a high voltage. Further, when the input is a DC voltage, the substrate in between the primary and secondary sides keeps the properties of a ceramic material has a high-impedance real-insulation state.

Below, the present invention is described in detail in cooperation with the drawings to make easily understood the objectives, characteristics and functions of the present invention.

### BRIEF DESCRIPTION OF THE DRAWINGS

FIG. 1A is a diagram schematically showing an insulation piezoelectric transformer according to an embodiment of the present invention;

FIG. 1B is a top view of an insulation piezoelectric transformer according to the same embodiment of the present invention;

FIG. 2 is a diagram schematically showing the polarization of an insulation piezoelectric transformer according to an embodiment of the present invention; and

FIG. 3A and FIG. 3B are diagrams schematically showing the polarization of an insulation piezoelectric transformer according to another embodiment of the present invention.

### DETAILED DESCRIPTION OF THE INVENTION

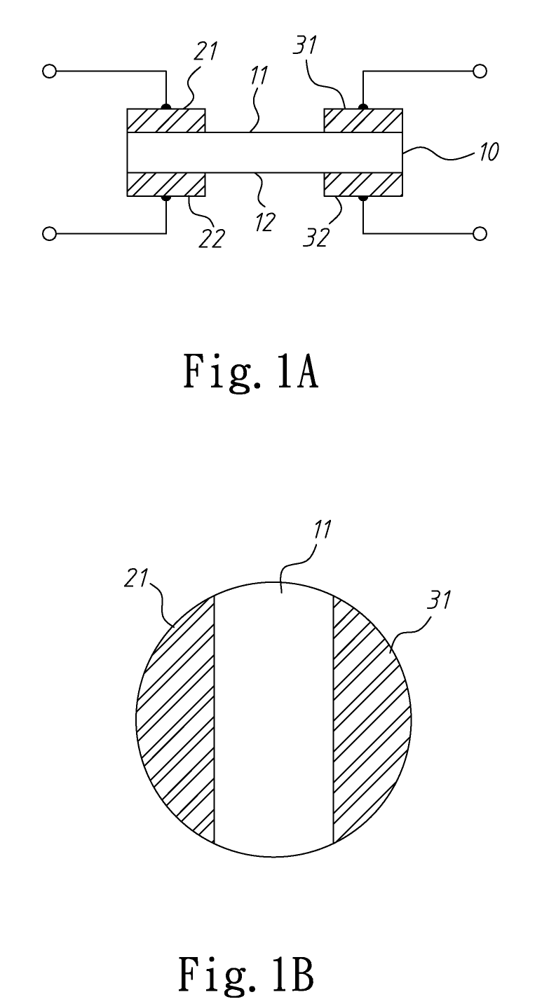

Refer to FIG. 1A a diagram schematically showing an insulation piezoelectric transformer according to an embodiment of the present invention.

In this embodiment, the insulation piezoelectric transformer of the present invention comprises a substrate 10, a first upper electrode 21, a first lower electrode 22, a second upper electrode 31 and a second lower electrode 32. Refer to FIG. 1B a top view of an insulation piezoelectric transformer according to the same embodiment of the present invention. The substrate 10 appears like a circle from the top view thereof and has an upper surface 11 and a lower surface 12 corresponding to each other. The substrate 10 may be fabricated via sintering a ceramic material. The first upper electrode 21 is formed on the upper surface 11 of the substrate 10 and has a shape of a bow. In other words, the first upper electrode 21 is defined by an arc and a chord, as shown in FIG. 1B. The first lower electrode 22 is formed on the lower surface 12 of the substrate 10 and symmetrical to the first upper electrode 21. In other words, the first upper and lower electrodes 21 and 22 are respectively formed on the upper and lower surfaces 11 and 12 of the substrate 10 and have about the same shape. The second upper electrode 31 is also formed on the upper surface 11 of the substrate 10 and also has a shape of a bow. The second lower electrode 32 is formed on the lower surface 12 of the substrate 10 and symmetrical to the second upper electrode 31. In other words, the second upper and lower electrodes 31 and 32 are respectively formed on the upper and lower surfaces 11 and 12 of the substrate 10 and have about the same shape. Alternatively, the substrate 10 may be designed to have a shape of a rectangle or another symmetric geometrical shape. The first upper and lower electrodes 21 and 22 always match the shape of the substrate 10 and keep symmetrical to each other, and the second upper and lower electrodes 31 and 32 also always match the shape of the substrate 10 and keep symmetrical to each other. The first upper electrode 21 does not contact the second upper electrode 31, and the first lower electrode 22 does not contact the second lower electrode 32 either. The abovementioned electrodes, including the first upper and lower electrodes 21 and 22 and the second upper and lower electrodes 31 and 32, are made of nickel, silver or copper, and formed with a coating method.

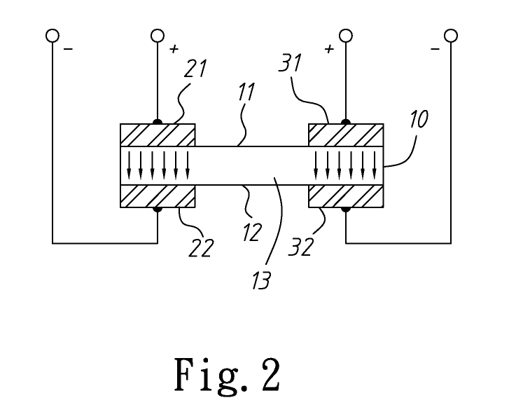

Refer to FIG. 2 a diagram schematically showing the polarization of an insulation piezoelectric transformer according to an embodiment of the present invention.

The substrate 10 between the first upper and lower electrodes 21 and 22 is polarized by applying a high DC voltage, such as an electric field having an intensity of 30 kV/cm, to the first upper and lower electrodes 21 and 22. The substrate 10 between the second upper and lower electrodes 31 and 32 is also polarized by applying a high DC voltage to the second upper and lower electrodes 31 and 32. The substrate 10 not covered by the first upper electrode 21, the first lower electrode 22, the second upper electrode 31 and the second lower electrode 32 maintains unpolarized and keeps the physical properties of ceramic. Thus, the first upper and lower electrodes 21 and 22 may function as the primary side of a transformer, and the second upper and lower electrodes 31 and 32 may function as the secondary side of the transformer.

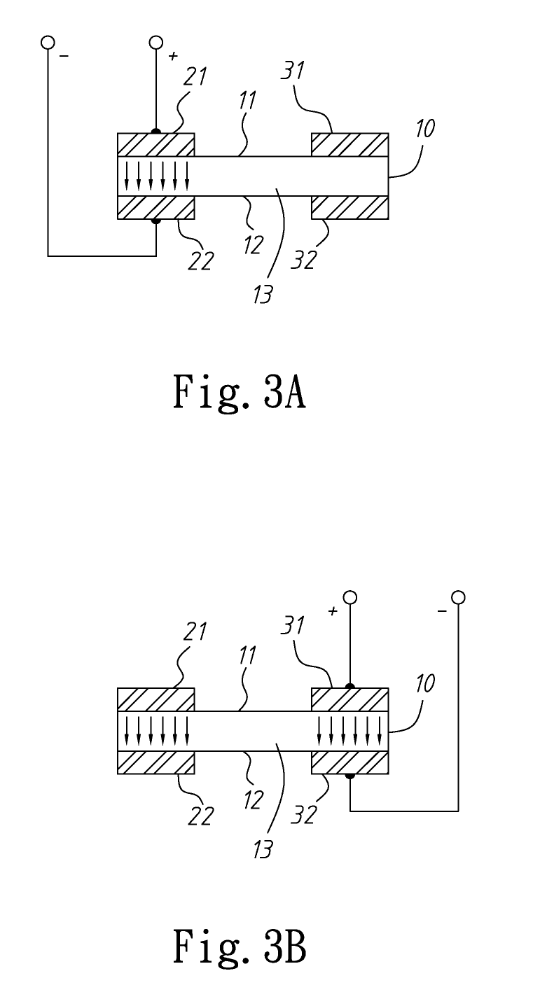

Refer to FIG. 3A and FIG. 3B diagrams schematically showing the polarization of an insulation piezoelectric transformer according to another embodiment of the present invention.

In this embodiment, the polarizations of the primary side and the secondary side are undertaken separately. As shown in FIG. 3A, the side where the first upper and lower electrodes 21 and 22 are located is polarized firstly. Then, as shown in FIG. 3B, the side where the second upper and lower electrodes 31 and 33 are located is also polarized. In the present invention, the polarization direction is arbitrary and not limited to that shown in the drawings. The impedance of the unpolarized area depends on the polarization process and the physical properties of the material. The separate polarizations make the unpolarized area have a higher impedance.

When a square wave is input into the primary side, the secondary side outputs a sinusoidal wave. General to speak, the transformer will have the highest power output when working at the resonant frequency. From experiments, it is known that the impedance of the unpolarized central area where the properties of a ceramic material are kept will increase with the decrease of the input frequency, and that the impedance has the minimum value at the range of the resonant frequency. When the input is a voltage without frequency, the impedance will reach as high as 10¹⁰-10¹¹ ohm. Thus, the transformer can function as an insulation transformer. When a malfunction (such as an OVP (Over-Voltage Protection) case or an OCP (Over-Current Protection) case) is detected on the load side, the abnormal-feedback protection circuit will send a signal to the control logic (CPU). The control logic then sends out a DC voltage to form a high impedance state between the primary side and the secondary side (real insulation).

In the present invention, the electrodes on the primary side and the secondary side have a large area and thus have a great capacitance. Therefore, the insulation piezoelectric transformer of the present invention can function as a high power isolation transformer. The first upper electrode 21 and the second upper electrode 22 are preferably of an identical shape and symmetrical with respect to the central line or diameter of the substrate 10. The insulation piezoelectric transformer of the present invention applies to LED illumination devices, backlight units, CCFL (Cold Cathode Fluorescent Lamp), backlight module inverters, EFFL (External Flat Fluorescent Lamp) ballasts, notebook computers, desktop computers, PDA, etc. The present invention is a single-layer isolation transformer; therefore, the present invention adapts to a PFC (Power Factor Corrector) DC 400V input. As the present invention needs neither a DC 400V step-down nor a DC 12-24V step-up in this case, the output efficiency thereof is better.

The embodiments described above are only to exemplify the present invention but not to limit the scope of the present invention. Therefore, any equivalent modification or variation according to the spirit of the present invention is to be also included within the scope of the present invention, which is based on the claims stated below.

What is claimed is:

1. An insulation piezoelectric transformer comprising
a substrate made of a ceramic material and having an upper surface and a lower surface;
a first upper electrode formed on said upper surface of said substrate;
a first lower electrode formed on said lower surface of said substrate and symmetrical to said first upper electrode, wherein applying a voltage to said first upper electrode and said first lower electrode polarizes one portion of said substrate in between said first upper electrode and said first lower electrode and enables said first upper electrode and said first lower electrode to function as a primary side;
a second upper electrode formed on said upper surface of said substrate and not contacting said first upper electrode;
a second lower electrode formed on said lower surface of said substrate and symmetrical to said second upper electrode, wherein applying a voltage to said second upper electrode and said second lower electrode polarizes one portion of said substrate in between said second upper electrode and said second lower electrode and enables said second upper electrode and said second lower electrode to function as a secondary side, and
wherein one portion of said substrate where none of said first upper electrode, said first lower electrode, said second upper electrode and said second lower electrode covers is not polarized and keeps properties of a ceramic material.

2. The insulation piezoelectric transformer of claim 1, wherein said primary side and said secondary side are polarized simultaneously.

3. The insulation piezoelectric transformer of claim 1, wherein said primary side and said secondary side are polarized separately.

4. The insulation piezoelectric transformer of claim 1, wherein said substrate has a shape of a circle or rectangle.

5. The insulation piezoelectric transformer of claim 4, wherein said first upper electrode and said second upper electrode are of an identical shape.

6. The insulation piezoelectric transformer of claim 5, wherein each of said first upper electrode and said second upper electrode has a shape of a bow or a rectangle.

7. The insulation piezoelectric transformer of claim 5, wherein said first upper electrode and said second upper electrode are symmetrical with respect to a central line or a diameter of said substrate.

8. The insulation piezoelectric transformer of claim 1, wherein said first upper electrode, said first lower electrode, said second upper electrode and said second lower electrode are made of nickel, silver, or copper.

9. The insulation piezoelectric transformer of claim 1, wherein when said primary side receives an input voltage without frequency, said portion of said substrate where none of said first upper electrode, said first lower electrode, said second upper electrode and said second lower electrode covers is in an insulation state.
